(19) United States
(12) Patent Application Publication
(10) Pub. No.: US 2009/0000108 A1
(43) Pub. Date: Jan. 1, 2009

(54) METHOD FOR STRUCTURING SOLAR MODULES AND STRUCTURING DEVICE

(76) Inventor: Dieter Manz, Schlaitdorf (DE)

Correspondence Address: Striker, Striker & Stenby, 103 East Neck Road, Huntington, NY, 11743, US

(21) Appl. No.: 11/933,789

(22) Filed: Nov. 1, 2007

(30) Foreign Application Priority Data
Nov. 2, 2006 (DE) 10 2006 051 556.0

(51) Int. Cl. G01R 31/28; B23P 21/00; H05K 13/04

(52) U.S. Cl. 29/729; 29/593; 29/705; 29/739

(57) ABSTRACT

For structuring solar modules, a track is inserted in a solar module by a structuring tool, and the inserted track is at the same time detected by a sensor following the structuring tool. This makes it possible to achieve quality control.

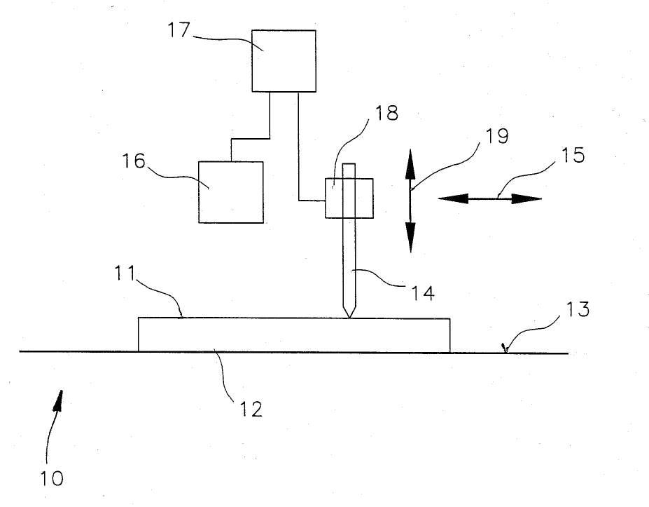

### CROSS-REFERENCE TO A RELATED APPLICATION

The invention described and claimed hereinbelow is also described in German Patent Application DE 10 2006 051 556.0 filed on Nov. 2, 2006. This German Patent Application, whose subject matter is incorporated here by reference, provides the basis for a claim of priority of invention under 35 U.S.C. 119(a)-(d).

### BACKGROUND OF THE INVENTION

The invention relates to a method for structuring solar modules in which a track is inserted in a solar module by means of a structuring tool, as well as a structuring device.

Glass substrates generally coated with three layers in coating installations are used to manufacture thin-film solar modules. For series connection of the individual cells inside a solar module, the layers are selectively separated in three structuring steps by inserting lines (tracks) into the solar modules.

If the track width is too great, the efficiency of the solar module suffers. In addition, short circuits can occur between the tracks.

### SUMMARY OF THE INVENTION

It is the object of the present invention to provide a method and a device with which the quality of an inserted track can be monitored.

This object is achieved in a surprising and simple manner by a method of the type specified initially in which the inserted track is detected by a following sensor. By means of this measure corrections can be made immediately to the structuring tool so that the quality of the remaining track to be inserted can be improved in the ongoing process. It is therefore particularly advantageous if the sensor is moved a short distance behind the structuring tool or at the same time as the structuring tool along the solar module.

In a particularly preferred variant of the method, it can be provided that the width and/or depth of the track is detected. The efficiency of a solar module can be improved if as little space as possible is required for the tracks. This is possible firstly if the tracks lie close to one another and secondly if the track width is small. The method according to the invention can ensure that the narrowest possible tracks can be inserted during the structuring. By detecting and monitoring the track depth, contact from one track through to another track in a different (lower-lying) layer and a short-circuit can be prevented.

The track is preferably detected optically. For example, the solar module can be irradiated by one or more light sources, in particular lasers or LEDs. One or more of the signals reflected by the solar module and/or one or more of the transmission signals can be detected and evaluated. For example, it is feasible that different wavelengths are detected and the corresponding information evaluated. For example, two measurement points can be recorded—in each case, one measurement point at an edge of the track to be detected. Alternatively, three measurement points can be recorded, in which case at least one measurement point should lie inside the track to be detected. Single- and multidimensional arrays or sensors, in particular CCD chips, for example can be used as detectors.

It is furthermore feasible to produce a confocal image and to determine depth information about the track which has just been inserted from this image. The structuring tool can be regulated on the basis of this depth information.

Particularly preferred is a variant of the method in which the profile of the inserted track is determined optically. In this case, both reflection and transmission properties of the substrate and the thin layers already applied can be used. The optical measurement can be made either from the underside of the substrate or from the coated top side of the substrate. The optical determination is particularly cost-effective.

Alternatively or additionally, the positions of a previously inserted track and the currently inserted track can be detected. In this case, the absolute positions or a relative position of the tracks to one another can be detected. By this means, the distance of the tracks can be measured and adjusted or optionally corrected for the subsequent process.

It is particularly preferable if at least one quantity describing the quality of the track is determined or detected and this quantity is compared with a reference quantity, wherein a quality improving measure can be initiated in the event of a predetermined result of the comparison. Quantities describing the quality of the track can be considered to be, for example, the track width, the track depth and the track distance. If a track width exceeding a predetermined width (too great track width) or a track depth exceeding a predetermined depth (too great track depth) is determined as the result of the comparison, a corrective action can be applied to the structuring tool. It can thus be monitored whether the inserted track moves within predefined tolerances. Two reference quantities, an upper and a lower limit, can also be predefined for this purpose, and adherence to these can be monitored. It can also be monitored that the tracks have a minimum distance and this can be influenced. Thus, the process parameters relevant for the width, depth or position can be varied as quality assurance measures.

Further advantages are obtained if the structuring of the solar module is effected by means of a laser and the laser power and/or the focal position and/or the beam profile of the laser is adjusted depending on the detected track width and/or track depth. By means of this measure, the laser used as a structuring tool can be regulated or controlled in particular in such a manner that an optimum width and depth of the track is achieved.

It can furthermore be provided that the structuring of the solar module is effected by means of a mechanical structuring tool, in particular a stylus and the contact pressure of the mechanical structuring tool on the solar module is adjusted depending on the detected track width and/or track depth. By means of this measure, the track depth and track width produced can be adjusted or corrected. In addition, it is possible to respond to different layer thicknesses. For example, these measures can avoid a thin layer being completely removed in the area of the track. At this point, it should be noted that in solar modules tracks are usually produced in three layers. In different layers the tracks can be inserted with different structuring tools, where the tracks in each layer can be monitored using a following sensor.

Alternatively or additionally, it can be provided that the structuring of the solar module is effected by means of a mechanical structuring tool, in particular a stylus and the mechanical structuring tool is re-sharpened depending on the detected track width and/or track depth. By detecting the track produced by means of a sensor, it can be identified when the mechanical structuring tool is blunt. The structuring process can then be interrupted to re-sharpen the mechanical tool or the track can be structured to the end and the structuring tool can be re-sharpened before it is used again for inserting a track.

In a preferred variant of the method it can be provided that a break in the solar module or a short circuit between tracks is concluded on the basis of the sensor signals. Such a solar module is scrap and can then be removed immediately, before further time and costs are expended in completing the solar module.

The scope of the invention also includes a structuring device for structuring solar modules, comprising a structuring tool, there being provided a sensor which follows the structuring tool and detects the track inserted by means of the structuring tool. Such a sensor can be used for quality control of the inserted track in real time. In the event of a faulty track being identified or a poor-quality track being detected or if the distance from a previously inserted track is too small or too great, this can be responded to immediately.

In this context, it is particularly advantageous if an evaluation device in data-technical communication with the sensor is provided for processing the sensor signals. The sensor signals can be evaluated in the evaluation device and in particular, an assessment can be made as to whether the track produced is moving within permissible tolerances. If this is not the case, appropriate measures can be initiated by the evaluation device which can be configured as a controller.

In particular, the evaluation device can be configured in such a manner that the sensor signals are directly evaluated in an analogue manner. The analogue signals can be fed directly to a controller of the structuring tool, for example, a laser. Furthermore, it is possible to feed the analogue signals to hardware and then further process them by means of software. On the basis of the detected signals, it can be determined, for example, whether the substrate is corrugated and whether re-focussing is necessary. This can be carried out if necessary.

If the structuring tool is a laser, particularly rapid regulation can be effected by measuring the intensity, for example, as sensor signals and supplying a corresponding analogue signal directly to the controller of the laser. The analogue signal can optionally be prepared beforehand.

The sensor or sensors preferably do not operate in a scanning mode. This means that preferably no scanning takes place in the transverse direction of the track. However, tracking transverse to the transverse direction of the track is effected in any case as a result of regulation. In order to find a starting point, it is optionally necessary to carry out an initial scanning process transverse to the structuring direction at the beginning of the track detection.

In a further development, an adjusting device can be provided for adjusting the structuring tool, said adjusting device being triggered by said evaluation device. In this case, the adjusting device can, for example, be a drive for height adjustment of a mechanical structuring tool. Alternatively it is feasible that the adjusting device is a power supply of a laser or adjustable focussing optics for a laser if the structuring tool is a laser.

In a particularly preferred embodiment of the invention, it can be provided that the sensor is configured as an optical sensor or as a mechanical sensor. The advantage of an optical sensor, for example, a camera with downstream image processing is that the inserted track can be detected in a contactless manner. Tracks are inserted in different layers. In this case, it is feasible that different sensors are provided for the different layers. In addition, on one solar module some tracks can be inserted by means of a laser and other tracks by means of a mechanical structuring tools such as for example a stylus. Different sensors can be provided for tracks inserted in different ways.

Further features and advantages of the invention are obtained from the following description of exemplary embodiments of the invention with reference to the FIGURE in the drawings which shows details important to the invention, and from the claims. The individual features can be implemented individually by themselves or as several in any combination in one variant of the invention.

Preferred exemplary embodiments of the invention are shown schematically in the drawings and are explained in detail hereinafter with reference to the FIGURE in the drawings.

### BRIEF DESCRIPTION OF THE DRAWINGS

The single FIGURE of the drawings is a view showing a structuring device for structuring solar modules in accordance with the present invention, by means of a method for structuring solar modules in accordance with the present invention.

### DESCRIPTION OF THE PREFERRED EMBODIMENTS

The single FIGURE shows a structuring device 10 highly schematically.

A track is inserted or scratched into the surface 11 of a solar module 12 located on a substrate 13 by means of a structuring tool 14 which in the exemplary embodiment is configured as a mechanical structuring tool, in particular as a stylus. This is accomplished by moving the structuring tool 14, for example in the direction of the double arrow 15 along the solar module 12 with a defined contact pressure.

A sensor 16 is moved jointly with the structuring tool 14 and detects the track inserted by the structuring tool 14. The sensor 16 and the structuring tool 14 are preferably mechanically coupled so that these are moved jointly. However, it is also feasible for the sensor 16 to be moved independently of the structuring tool 14.

The sensor 16 is in data-technical communication with an evaluation device 17 which assesses the quality of the detected track width. Depending on this assessment, an adjusting device 18 configured as a drive can be triggered whereby the structuring tool 14 can be moved in the direction of the double arrow 19 in order to vary the contact pressure and therefore the track depth and track width.

Further drives can also be provided, these being required to move the structuring tool 14 in the direction of the double arrow 15 or obliquely thereto. These drives can also be triggered by the evaluation device 17 or a controller of which the evaluation device 17 can be a component.

It will be understood that each of the elements described above, or two or more together, may also find a useful application in other types of methods and constructions differing from the type described above.

While the invention has been illustrated and described as embodied in a method for structuring solar modules and structuring device, it is not intended to be limited to the details shown, since various modifications and structural changes may be made without departing in any way from the spirit of the present invention.

Without further analysis, the foregoing will so fully reveal the gist of the present invention that others can, be applying current knowledge, readily adapt it for various applications without omitting features that, from the standpoint of prior art, fairly constitute essential characteristics of the generic or specific aspects of this invention.

What is claimed as new and desired to be protected by Letters Patent is set forth in the appended claims:

1. A method of structuring solar modules, comprising the steps of inserting a track in a solar module by a structuring tool; and detecting the inserted track at the same time by a sensor following the structuring tool.

2. A method as defined in claim 1, wherein said detecting includes detecting a parameter of the track selected from the group consisting a width of the track, a depth of the track, and both.

3. A method as defined in claim 1, wherein said detecting includes detecting positions of a previously inserted track and a currently inserted track.

4. A method as defined in claim 1; and further comprising determining or detecting at least one quantity describing a quality of the track; and comparing this quantity with a reference quantity, wherein a quality improving measure is initiatable in an event of a predetermined result of the comparison.

5. A method as defined in claim 1, wherein said structuring of the solar module includes a structuring by a laser; and further comprising adjusting a parameter of the laser selected from the group consisting of a laser power, a focal position, a beam profile, and combination thereof, depending on a parameter of the detected track selected from the group consisting of a track width, a track depth, and both.

6. A method as defined in claim 1, wherein said structuring of the solar module includes a structuring by a mechanical structuring tool, in particular a stylus; and further comprising adjusting a contact pressure of the mechanical structuring tool depending on a parameter selected from the group consisting of a detected track width, a detected track depth, and both.

7. A method as defined in claim 1, wherein said structuring of the solar module includes a structuring by a mechanical structuring tool, in particular a stylus; and further comprising re-sharpening of the mechanical structuring tool depending on a parameter selected from the group consisting of a detected track width, a detected track depth, and both.

8. A method as defined in claim 1; and further comprising concluding an event selected from the group consisting of a break in the solar module and a short circuit between tracks, on a basis of signals of the sensor.

9. A structuring device for structuring solar modules, comprising a structuring tool; and a sensor which follows said structuring tool and detects a track inserted by the structuring tool.

10. A structuring device as defined in claim 9; and further comprising an evaluation device in a data-technical communication with said sensor for processing signals of the sensor.

11. A structuring device as defined in claim 10; and further comprising an adjusting device for adjusting the structural tool and triggerable by said evaluation device.

12. A structuring device as defined in claim 9, wherein said sensor is configured as a sensor selected from the group consisting of an optical sensor and a mechanical sensor.
